(19) United States
(12) Patent Application Publication
(10) Pub. No.: US 2007/0032044 A1
(43) Pub. Date: Feb. 8, 2007

(54) Method and structure for fabricating devices using one or more films provided by a layer transfer process and etch back

(75) Inventor: Francois J. Henley, Aptos, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silicon Genesis Corporation, San Jose, CA (US)

(21) Appl. No.: 11/199,987

(22) Filed: Aug. 8, 2005

(51) Int. Cl. H01L 21/30; H01L 21/311

(52) U.S. Cl. 438/459; 438/458; 438/697; 438/455

(57) ABSTRACT

A method for fabricating one or more devices using semiconductor substrate with a cleave region. The method includes providing a substrate. In a preferred embodiment, the substrate has a thickness of semiconductor material and a surface region. In a specific embodiment, the substrate also has a cleave plane (including a plurality of particles, deposited material, or any combination of these, and the like) provided within the substrate, which defines the thickness of semiconductor material. The method includes joining the surface region of the substrate to a first handle substrate. In a preferred embodiment, the method includes initiating a controlled cleaving action at a portion of the cleave plane to detach the thickness of semiconductor material from the substrate, while the thickness of semiconductor material remains joined to the first handle substrate. The method includes processing the first handle substrate with the thickness of semiconductor material using one or more processes to form at least one integrated circuit device onto a portion of the thickness of semiconductor material. In a preferred embodiment, the processing includes high temperature semiconductor processing techniques to form conventional integrated circuits thereon. The method forms a planarized surface region overlying the thickness of semiconductor material. The method also joins the planarized surface region to a face of a second handle substrate. The method selectively removing the first handle substrate from the thickness of semiconductor material, while the face of the second handle substrate remains joined to the planarized surface region.

### BACKGROUND OF THE INVENTION

The present invention relates to the manufacture of substrates. More particularly, the invention provides a technique including a method and a structure for forming multi-layered substrate structures for the fabrication of substrates for semiconductor integrated circuit devices using layer transfer techniques. But it will be recognized that the invention has a wider range of applicability; it can also be applied to other types of substrates for three-dimensional packaging of integrated semiconductor devices, photonic devices, piezoelectronic devices, flat panel displays, microelectromechanical systems (“MEMS”), nano-technology structures, sensors, actuators, solar cells, biological and biomedical devices, and the like.

From the very early days, human beings have been building useful articles, tools, or devices using less useful materials for numerous years. In some cases, articles are assembled by way of smaller elements or building blocks. Alternatively, less useful articles are separated into smaller pieces to improve their utility. A common example of these articles to be separated include substrate structures, such as a glass plate, a diamond, a semiconductor substrate, a flat panel display, and others. These substrate structures are often cleaved or separated using a variety of techniques. In some cases, the substrates can be separated using a saw operation. The saw operation generally relies upon a rotating blade or tool, which cuts through the substrate material to separate the substrate material into two pieces. This technique, however, is often extremely “rough” and cannot generally be used for providing precision separations in the substrate for the manufacture of fine tools and assemblies. Additionally, the saw operation often has difficulty separating or cutting extremely hard and or brittle materials, such as diamond or glass. The saw operation also cannot be used effectively for the manufacture of microelectronic devices, including integrated circuit devices, and the like.

Accordingly, techniques have been developed to fabricate microelectronic devices, commonly called semiconductor integrated circuits. Such integrated circuits are often developed using a technique called the “planar process” developed in the early days of semiconductor manufacturing. An example of one of the early semiconductor techniques is described in U.S. Pat. No. 2,981,877, in the name of Robert Noyce, who has been recognized as one of the father's of the integrated circuit. Such integrated circuits have evolved from a handful of electronic elements into millions and even billions of components fabricated on a small slice of silicon material. Such integrated circuits have been incorporated into and control many of today's devices, such as computers, cellular phones, toys, automobiles, and all types of medical equipment.

Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits. Increasing circuit density has not only improved the complexity and performance of integrated circuits but has also provided lower cost parts to the consumer.

Making devices smaller is very challenging, as each process used in integrated fabrication has a limit. That is to say, a given process typically only works down to a certain feature size, and then either the process or the device layout needs to be changed. Additionally, as devices require faster and faster designs, process limitations exist with certain conventional processes and materials. An example of such a process is an ability to make the thickness of the substrate thin after the manufacture of the integrated circuit devices thereon. A conventional process often used to thin these device layers is often called “back grinding,” which is often cumbersome, prone to cause device failures, and can only thin the device layer to a certain thickness. Although there have been significant improvements, such back grinding processes still have many limitations.

Accordingly, certain techniques have been developed to cleave a thin film of crystalline material from a larger donor substrate portion. These techniques are commonly known as “layer transfer” processes. Such layer transfer processes have been useful in the manufacture of specialized substrate structures, such as silicon on insulator or display substrates. As merely an example, a pioneering technique was developed by Francois J. Henley and Nathan Chung to cleave films of materials. Such technique has been described in U.S. Pat. No. 6,013,563 titled Controlled Cleaving Process, assigned to Silicon Genesis Corporation of San Jose, Calif., and hereby incorporated by reference for all purposes. Although such technique has been successful, there is still a desire for improved ways of manufacturing multilayered structures.

From the above, it is seen that a technique for manufacturing large substrates which is cost effective and efficient is desirable.

### BRIEF SUMMARY OF THE INVENTION

According to the present invention, techniques related to the manufacture of substrates are provided. More particularly, the invention provides a technique including a method and a structure for forming multi-layered substrate structures for the fabrication of substrates for semiconductor integrated circuit devices using layer transfer techniques. But it will be recognized that the invention has a wider range of applicability; it can also be applied to other types of substrates for three-dimensional packaging of integrated semiconductor devices, photonic devices, piezoelectronic devices, flat panel displays, microelectromechanical systems (“MEMS”), nano-technology structures, sensors, actuators, solar cells, biological and biomedical devices, and the like.

In a specific embodiment, the present invention provides a method for fabricating one or more devices using semiconductor substrate with a cleave region. The method includes providing a substrate, e.g., silicon, germanium, a silicon-germanium alloy, gallium arsenide, any Group III/V materials, and others. In a preferred embodiment, the substrate has a thickness of semiconductor material and a surface region. In a specific embodiment, the substrate also has a cleave plane (including a plurality of particles (e.g., hydrogen species), deposited material, or any combination of these, and the like) provided within the substrate, which defines the thickness of semiconductor material. The method includes joining the surface region of the substrate to a first handle substrate. In a preferred embodiment, the method includes initiating a controlled cleaving action at a portion of the cleave plane to detach the thickness of semiconductor material from the substrate, while the thickness of semiconductor material remains joined to the first handle substrate. The method includes processing the first handle substrate with the thickness of semiconductor material using one or more processes to form at least one integrated circuit device onto a portion of the thickness of semiconductor material. In a preferred embodiment, the processing includes high temperature semiconductor processing techniques to form conventional integrated circuits thereon. The method forms a planarized surface region overlying the thickness of semiconductor material. The method also joins the planarized surface region to a face of a second handle substrate, e.g., glass, silicon, polysilicon, single crystal silicon, amorphous silicon, quartz, glass, polymer (e.g., plastic), any combination of these, and others. The method selectively removing the first handle substrate from the thickness of semiconductor material, while the face of the second handle substrate remains joined to the planarized surface region.

In an alternative specific embodiment, the present invention provides a method for fabricating one or more devices using a layer transfer process. The method includes providing a semiconductor substrate, which has a thickness of semiconductor material and a surface region. In a preferred embodiment, the semiconductor substrate also has a cleave plane including a plurality of hydrogen species provided within the semiconductor substrate and defining the thickness of semiconductor material. The method joins the surface region of the semiconductor substrate to a first handle substrate using at least a bonding process. The method includes initiating a cleaving action at a portion of the cleave plane to detach the thickness of semiconductor material from the semiconductor substrate, while the thickness of semiconductor material remains joined to the first handle substrate. The method also includes processing the first handle substrate with the thickness of semiconductor material using one or more processes to form at least one integrated circuit device onto a portion of the thickness of semiconductor material. In a preferred embodiment, the first handle substrate remains firmly attached to the thickness of material without any blistering, delaminating, or other imperfections. The method includes forming a planarized surface region overlying the thickness of semiconductor material. The method also includes joining the planarized surface region using at least a bonding process to a face of a second handle substrate. In a preferred embodiment, the method selectively removes the first handle substrate from the thickness of semiconductor material, while the face of the second handle substrate remains joined to the planarized surface region.

Numerous benefits are achieved over pre-existing techniques using the present invention. In particular, the present invention uses controlled energy and selected conditions to preferentially cleave a thin film of material without a possibility of damage to such film from excessive energy release. This cleaving process selectively removes the thin film of material from the substrate while preventing a possibility of damage to the film or a remaining portion of the substrate. Additionally, the present method and structures allow for more efficient processing using a cleave layer provided in a substrate through the course of semiconductor processing, which may occur at higher temperatures, according to a specific embodiment. Once the cleaved layer has been subjected to integrated circuit processing techniques, a handle substrate, which held the cleaved layer is selectively removed using a selective etching process and/or a combination of etching and other thinning techniques, e.g., back-grinding, chemical mechanical polishing, etc. Depending upon the embodiment, one or more of these benefits may be achieved. These and other benefits may be described throughout the present specification and more particularly below.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 illustrates an overall simplified method for manufacturing integrated circuits on a layer transferred substrate according to embodiments of the present invention.

FIGS. 2 through 10 illustrate a simplified method for manufacturing integrated circuits on a layer transferred substrate according to embodiments of the present invention.

### DETAILED DESCRIPTION OF THE INVENTION

According to the present invention, techniques related to the manufacture of substrates are provided. More particularly, the invention provides a technique including a method and a structure for forming multi-layered substrate structures for the fabrication of substrates for semiconductor integrated circuit devices using layer transfer techniques. But it will be recognized that the invention has a wider range of applicability; it can also be applied to other types of substrates for three-dimensional packaging of integrated semiconductor devices, photonic devices, piezoelectronic devices, flat panel displays, microelectromechanical systems (“MEMS”), nano-technology structures, sensors, actuators, solar cells, biological and biomedical devices, and the like.

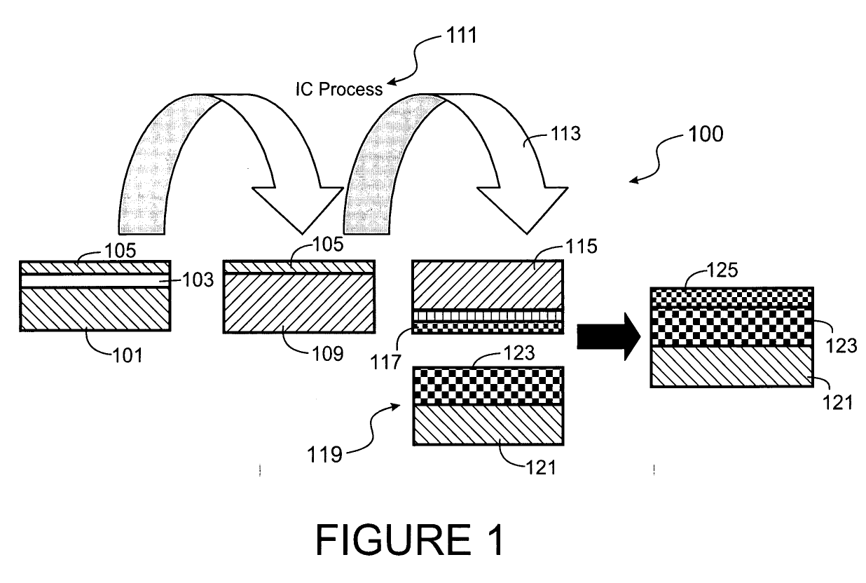

Referring to FIG. 1, a method 100 for fabricating integrated circuits on a layer transferred substrate according to embodiments of the present invention may be outlined as follows:

1 Provide a semiconductor substrate 101, e.g., silicon, germanium, a silicon-germanium alloy, gallium arsenide, any Group III/V materials, and others;

2. Form a cleave plane 103 (including a plurality of particles, deposited material, or any combination of these, and the like) to define a thickness of semiconductor material 105 provided within the semiconductor substrate;

3. Join the surface region of the substrate to a first handle substrate 109, which has desired characteristics for processing but will later be removed;

4. Initiate a controlled cleaving action at a portion of the cleave plane to detach the thickness of semiconductor material from the substrate, while the thickness of semiconductor material remains joined 105 to the first handle substrate 109;

5. Process (step 111) the first handle substrate with the thickness of semiconductor material using one or more processes (step 113) to form at least one integrated circuit device onto a portion of the thickness of semiconductor material, while the thickness of semiconductor material remains joined to the first handle substrate;

6. Form a planarized surface region overlying the thickness of semiconductor material;

7. Join the planarized surface region 117 of the first substrate 115 to a face 123 of a second handle substrate 119, which may include a bulk substrate material 121;

8. Selectively remove the first handle substrate from the thickness of semiconductor material, while the face of the second handle substrate remains joined to the planarized surface region;

9. Form a resulting second handle substrate 121 including the thickness of material 125 with at least one integrated circuit device thereon;

10. Optionally, the above steps can be repeated to for at least one or more layers 123, which includes other integrated circuit device elements or other features; and

11. Perform other steps, as desired.

The above sequence of steps provides a method according to an embodiment of the present invention. As shown, the method uses a combination of steps including a way of forming a handle substrate including a thickness of material, which is subjected to processing. The handle substrate is selectively removed after processing while the thickness of material large substrate is transferred to another substrate structure according to a specific embodiment. Other alternatives can also be provided where steps are added, one or more steps are removed, or one or more steps are provided in a different sequence without departing from the scope of the claims herein. Further details of the present method can be found throughout the present specification and more particularly below.

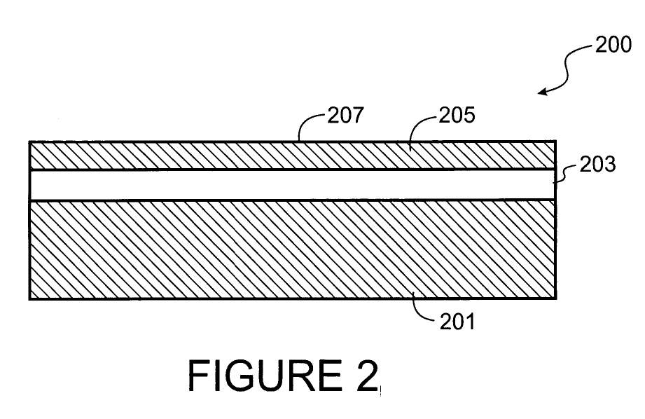

FIGS. 2 through 10 illustrate a simplified method for manufacturing integrated circuits on a layer transferred substrate according to embodiments of the present invention. These diagrams are merely illustrations that should not unduly limit the scope of the claims herein. One of ordinary skill in the art would recognize other variations, modifications, and alternatives. As shown, the method includes providing a semiconductor substrate 200, e.g., silicon, germanium, a silicon-germanium alloy, gallium arsenide, any Group III/V materials, and others. In a specific embodiment, the semiconductor substrate can be made of a single homogenous material, or a combination of various layers, depending upon the specific embodiment. Of course, there can be other variations, modifications, and alternatives.

In a preferred embodiment, FIG. 2 shows substrate 201 having a thickness of semiconductor material 205 and a surface region 207. In a specific embodiment, the substrate also has a cleave plane 203 (including a plurality of particles, deposited material, or any combination of these, and the like) provided within the substrate, which defines the thickness of semiconductor material. Of course, there can be other variations, modifications, and alternatives.

Depending upon the embodiment, the cleave region can be formed using a variety of techniques. That is, the cleave region can be formed using any suitable combination of implanted particles, deposited layers, diffused materials, patterned regions, and other techniques. In a specific embodiment, the method introduces certain energetic particles using an implant process through a top surface of the semiconductor substrate, which can be termed a donor substrate, to a selected depth, which defines the thickness of the semiconductor material region, termed the “thin film” of material. A variety of techniques can be used to implant the energetic particles into a single crystal silicon wafer according to a specific embodiment. These techniques include ion implantation using, for example, beam line ion implantation equipment manufactured from companies such as Applied Materials, Inc. and others. Alternatively, implantation occurs using a plasma immersion ion implantation (“PIII”) technique, ion shower, and other non-mass specific techniques can be particularly effective for larger surface regions according to a specific embodiment. Combination of such techniques may also be used. Of course, techniques used depend upon the application.

Depending upon the application, smaller mass particles are generally selected to reduce a possibility of damage to the material region according to a preferred embodiment. That is, smaller mass particles easily travel through the substrate material to the selected depth without substantially damaging the material region that the particles traverse through. For example, the smaller mass particles (or energetic particles) can be almost any charged (e.g., positive or negative) and or neutral atoms or molecules, or electrons, or the like. In a specific embodiment, the particles can be neutral and or charged particles including ions such as ions of hydrogen and its isotopes, rare gas ions such as helium and its isotopes, and neon, or others depending upon the embodiment. The particles can also be derived from compounds such as gases, e.g., hydrogen gas, water vapor, methane, and hydrogen compounds, and other light atomic mass particles. Alternatively, the particles can be any combination of the above particles, and or ions and or molecular species and or atomic species. The particles generally have sufficient kinetic energy to penetrate through the surface to the selected depth underneath the surface.

Using hydrogen as the implanted species into the silicon wafer as an example, the implantation process is performed using a specific set of conditions. Implantation dose ranges from about 10¹⁵ to about 10¹⁸ atoms/cm², and preferably the dose is greater than about 10¹⁶ atoms/cm². Implantation energy ranges from about 1 KeV to about 1 MeV, and is generally about 50 KeV. Implantation temperature ranges from about −20 to about 600 Degrees Celsius, and is preferably less than about 400 Degrees Celsius to prevent a possibility of a substantial quantity of hydrogen ions from diffusing out of the implanted silicon wafer and annealing the implanted damage and stress. The hydrogen ions can be selectively introduced into the silicon wafer to the selected depth at an accuracy of about ±0.03 to ±0.05 microns. Of course, the type of ion used and process conditions depend upon the application.

Effectively, the implanted particles add stress or reduce fracture energy along a plane parallel to the top surface of the substrate at the selected depth. The energies depend, in part, upon the implantation species and conditions. These particles reduce a fracture energy level of the substrate at the selected depth. This allows for a controlled cleave along the implanted plane at the selected depth. Implantation can occur under conditions such that the energy state of the substrate at all internal locations is insufficient to initiate a non-reversible fracture (i.e., separation or cleaving) in the substrate material. It should be noted, however, that implantation does generally cause a certain amount of defects (e.g., micro-detects) in the substrate that can typically at least partially be repaired by subsequent heat treatment, e.g., thermal annealing or rapid thermal annealing. In a specific embodiment, the cleave region has been a weakened region, using particles and/or deposited materials. Of course, there can be other variations, modifications, and alternatives.

In a specific embodiment, the substrate surface region can have a certain characteristic before implanting. In a specific embodiment, a silicon wafer may have a thin layer of oxide overlying the silicon wafer. The layer of oxide is provided overlying the thickness of material, which will be implanted and cleaved according to a specific embodiment. Of course, there can be various modifications, alternatives, and variations.

Depending upon the embodiment, there may be other techniques for forming a cleave region and/or cleave layer. As merely an example, such cleave region is formed using other processes, such as those using a silicon-germanium cleave plane developed by Silicon Genesis Corporation of Santa Clara, Calif. and processes such as the SmartCut™ process of Soitec SA of France, and the Eltran™ process of Canon Inc. of Tokyo, Japan, any like processes, and others. Of course, there may be other variations, modifications, and alternatives.

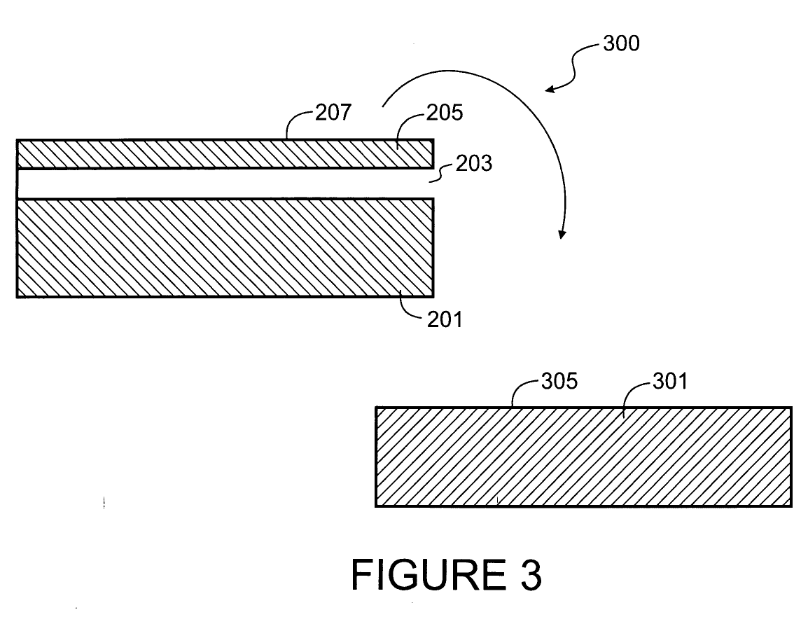

Referring now to FIG. 3, the method includes joining 300 the surface region of the semiconductor substrate to a first handle substrate 301. In a specific embodiment, the handle substrate is made of a suitable material that can be later removed using a selective removal process. That is, the handle substrate can be made of a glass and/or quartz material according to a specific embodiment. The glass and/or quartz can be used with a silicon donor substrate material according to a specific embodiment. Of course, there can be other handle substrate material such as materials that have accelerated etch characteristics depending upon the specific embodiment. On such accelerated etch material is a layer of porous silicon prepared on top of a silicon substrate. The porous layer can be made thick enough to allow for lateral etching of the substrate to detach it from the processed surface film region. Other types of materials such as polymers (e.g., plastic), including any combination of the above, may also be used according to a specific embodiment.

In a preferred embodiment, the first handle substrate has a surface region 305, which will be joined and/or bonded with surface region 207 provided on substrate 201. Like reference numerals are used in this figure has others, but are not intended to be limiting the scope of the claims herein. Further details of the joining process can be found throughout the present specification and more particularly below.

Before joining, the semiconductor substrate and the first handle substrate surfaces are each subjected to a cleaning solution to treat the surfaces of the substrates to clean the substrate surface regions according to a specific embodiment. An example of a solution used to clean the substrate and handle surfaces is a mixture of hydrogen peroxide and sulfuric acid, and other like solutions. A dryer dries the semiconductor substrate and handle surfaces to remove any residual liquids and/or particles from the substrate surfaces. Self-bonding occurs by placing surfaces of cleaned substrates (e.g., semiconductor substrate surface and handle substrate surface) together after an optional plasma activation process depending on the specific layer-transfer process used. If desired, such plasma activated processes clean and/or activate the surfaces of the substrates. The plasma activated processes are provided, for example, using an oxygen or nitrogen bearing plasma at 20° C. to 40° C. temperature. The plasma activated processes are preferably carried out in dual frequency plasma activation system manufactured by Silicon Genesis Corporation of San Jose, Calif. Of course, there can be other variations, modifications, and alternatives, which have been described herein, as well as outside of the present specification.

Thereafter, each of these substrates is bonded together according to a specific embodiment. As shown, the handle substrate has been bonded to the donor substrate surface region. The substrates are preferably bonded using an EVG 850 bonding tool manufactured by Electronic Vision Group or other like processes for smaller substrate sizes such as 200 mm or 300 mm diameter wafers. Other types of tools such as those manufactured by Karl Suss may also be used. Of course, there can be other variations, modifications, and alternatives. Preferably, bonding between the handle substrate and the donor is substantially permanent and has good reliability.

Accordingly after bonding according to a specific embodiment, the bonded substrate structures are subjected to a bake treatment. The bake treatment maintains the bonded substrate at a predetermined temperature and predetermined time. Preferably, the temperature ranges from about 200 or 250 Degrees Celsius to about 400 Degrees Celsius and is preferably about 350 Degrees Celsius for about 1 hour or so for a silicon donor substrate and the first handle substrate to attach themselves to each other permanently according to the preferred embodiment. Depending upon the specific application, there can be other variations, modifications, and alternatives. Of course, the bake treatment can be optional or preferred according to a specific embodiment.

In a specific embodiment, the substrates are joined or fused together using a low temperature thermal step. The low temperature thermal process generally ensures that the implanted particles do not place excessive stress on the material region, which can produce an uncontrolled cleave action. In a specific embodiment, the low temperature bonding process occurs by a self-bonding process.

Alternatively, an adhesive disposed on either or both surfaces of the substrates, which bond one substrate to another substrate. In a specific embodiment, the adhesive includes an epoxy, polyimide-type materials, and the like. Spin-on-glass layers can be used to bond one substrate surface onto the face of another. These spin-on-glass (“SOG”) materials include, among others, siloxanes or silicates, which are often mixed with alcohol-based solvents or the like. SOG can be a desirable material because of the low temperatures (e.g., 150 to 250 degree C.) often needed to cure the SOG after it is applied to surfaces of the wafers.

Alternatively, a variety of other low temperature techniques can be used to join the donor substrate surface regions to the handle substrate. For instance, an electro-static bonding technique can be used to join the two substrates together. In particular, one or both substrate surface(s) is charged to attract to the other substrate surface. Additionally, the donor substrate surface can be fused to the handle wafer using a variety of other commonly known techniques. Alternatively, anodic bonding techniques may also be used alone or in combination with any of the techniques described herein as well as others, according to a specific embodiment. Of course, the technique used depends upon the application.

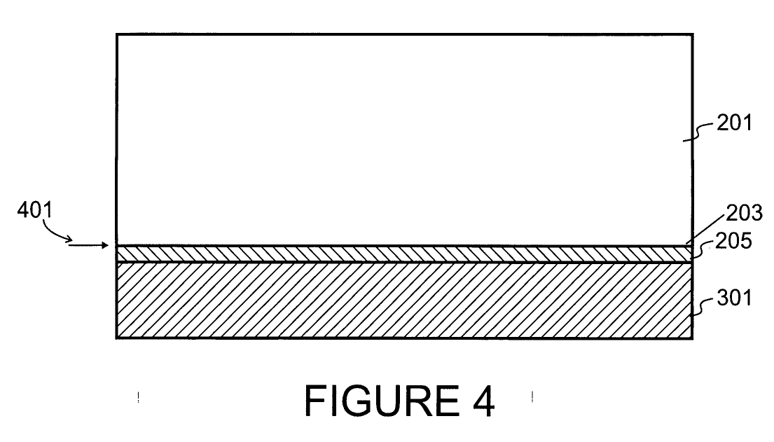

Referring to FIG. 4, the method includes initiating a controlled cleaving action using energy 401 provided at a selected portion of the cleave plane to detach the thickness of semiconductor material from the substrate, while the thickness of semiconductor material remains joined to the first handle substrate. Depending upon the specific embodiment, there can be certain variations. For example, the cleaving process can be a controlled cleaving process using a propagating cleave front to selectively free the thickness of material from the donor substrate attached to the handle substrate. Alternative techniques for cleaving can also be used. Such techniques, include, but are not limited to those called a Nanocleave™ process of Silicon Genesis Corporation of Santa Clara, Calif., a SmartCut™ process of Soitec SA of France, and an Eltran process of Canon Inc. of Tokyo, Japan, any like processes, and others. The method then removes the remaining portion of the semiconductor donor substrate, which provided the thickness of material to the handle substrate according to a specific embodiment.

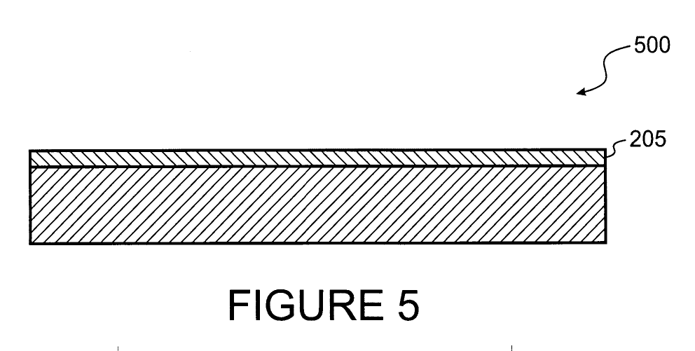

Referring to FIG. 5, the method provides a resulting handle substrate 500 including an overlying thickness of material 205 according to a preferred embodiment. In a specific embodiment, the resulting handle substrate has suitable characteristics for undergoing one or more processing steps. That is, the handle substrate can be subjected to conventional semiconductor processing techniques, including but not limited to, photolithography, etching, implanting, thermal annealing, chemical mechanical polishing, diffusion, deposition, and other others, which may be known by one of ordinary skill in the art. The handle substrate can also be selectively removed while transferring the thin film of material onto another substrate structure according to a specific embodiment.

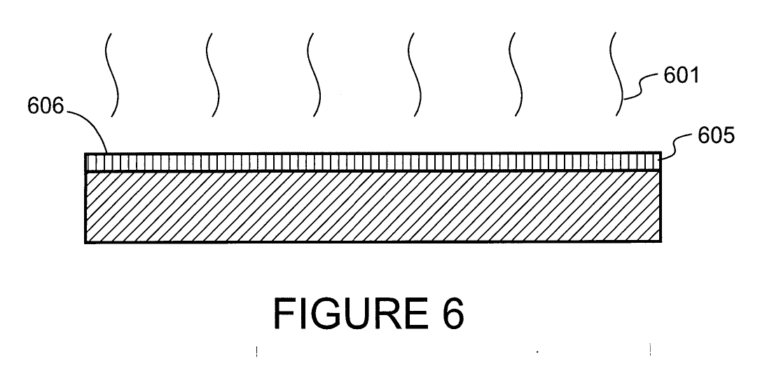

Referring to FIG. 6, the present method performs other processes on portions of the donor substrate regions, which have been attached to the handle substrate. The method forms one or more devices 605 on one or more portions of the thin film of material overlying the handle substrate surface. Such devices can include integrated semiconductor devices (e.g., bipolar, MOS, CMOS), photonic and/or optoelectronic devices (e.g., light valves), piezoelectronic devices, microelectromechanical systems (“MEMS”), nano-technology structures, sensors, actuators, solar cells, flat panel display devices (e.g., LCD, AMLCD), biological and biomedical devices, and the like. Such devices can be made using deposition, etching, implantation, photo masking processes, any combination of these, and the like. Of course, there can be other variations, modifications, and alternatives. Additionally, other steps can also be formed, as desired. In a preferred embodiment, the processing includes high temperature semiconductor processing techniques 601 to form conventional integrated circuits thereon.

In a specific embodiment, the method forms a planarized surface region 606 overlying the thickness of semiconductor material. In a specific embodiment, the planarized surface region can be formed using one or more suitable techniques. Such techniques include deposition of a dielectric layer, which is later reflowed using thermal treatment. The planarized surface region can also be formed using a chemical mechanical polishing process including a suitable slurry, pad, and process according to a specific embodiment. The planarized surface region can also be formed using any combination of these techniques and others (e.g., etch back, reflow, conformal deposition with high gap filling properties) according to a specific embodiment. The planarized surface region preferably has a uniformity of about 0.1% to about 5% end to end, and is within about 15 Angstroms RMS in roughness as measured on a 2 micron by 2 micron atomic-force microscope scan. Of course, there can be other variations, modifications, and alternatives.

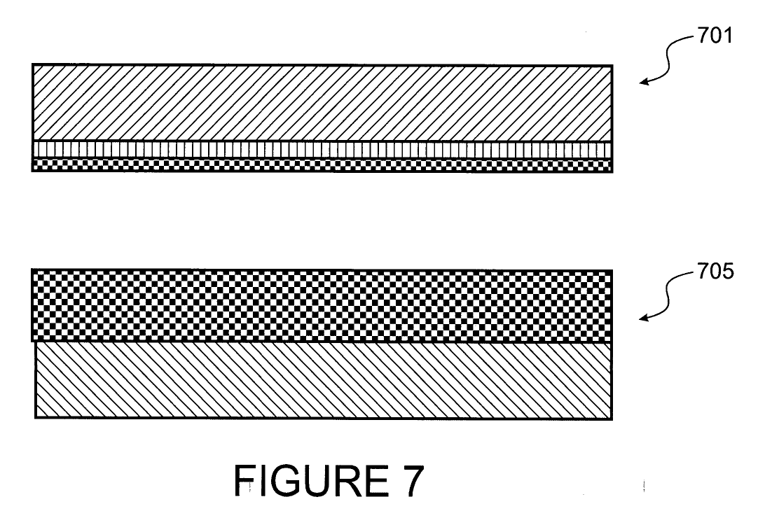

In a specific embodiment, the method also joins the planarized surface region of the resulting processed handle substrate 701 to a face of a second handle substrate 705, as illustrated by FIG. 7. Before joining, the processed thickness of material and the second handle substrate surfaces are each subjected to a cleaning solution to treat the surfaces of the substrates to clean the substrate surface regions according to a specific embodiment. An example of a solution used to clean the substrate and handle surfaces is a mixture of hydrogen peroxide and sulfuric acid, and other like solutions. A dryer dries the semiconductor substrate and handle surfaces to remove any residual liquids and/or particles from the substrate surfaces. Self-bonding occurs by placing surfaces of cleaned substrates (e.g., planarized region and handle substrate surface) together after an optional plasma activation process depending on the specific layer-transfer process used. If desired, such plasma activated processes clean and/or activate the surfaces of the processed substrates. The plasma activated processes are provided, for example, using an oxygen or nitrogen bearing plasma at 20° C. to 40° C. temperature. The plasma activated processes are preferably carried out in dual frequency plasma activation system manufactured by Silicon Genesis Corporation of San Jose, Calif. Of course, there can be other variations, modifications, and alternatives, which have been described herein, as well as outside of the present specification.

Thereafter, each of these substrates (and processed devices) is bonded together according to a specific embodiment. As shown, the handle substrate has been bonded to the planarized surface region. The substrates are preferably bonded using an EVG 850 bonding tool manufactured by Electronic Vision Group or other like processes for smaller substrate sizes such as 200 mm or 300 mm diameter wafers. Other types of tools such as those manufactured by Karl Suss may also be used. Of course, there can be other variations, modifications, and alternatives. Preferably, bonding between the handle substrate and the planarized surface is substantially permanent and has good reliability.

Accordingly after bonding, the bonded substrate structures are subjected to a bake treatment according to a specific embodiment. The bake treatment maintains the bonded substrate at a predetermined temperature and predetermined time. Preferably, the temperature ranges from about 200 or 250 Degrees Celsius to about 400 Degrees Celsius and is preferably about 350 Degrees Celsius for about 1 hour or so for a planarized substrate region and the second handle substrate to attach themselves to each other permanently according to the preferred embodiment. Depending upon the specific application, there can be other variations, modifications, and alternatives. Additionally, the bake treatment may be optional according to a specific embodiment.

In a specific embodiment, the substrates are joined or fused together using a low temperature thermal step. The low temperature thermal process generally ensures that the implanted particles do not place excessive stress on the material region, which can produce an uncontrolled cleave action. In a specific embodiment, the low temperature bonding process occurs by a self-bonding process.

Alternatively, an adhesive disposed on either or both surfaces of the substrates, which bond one substrate to another substrate. In a specific embodiment, the adhesive includes an epoxy, polyimide-type materials, and the like. Spin-on-glass layers can be used to bond one substrate surface onto the face of another. These spin-on-glass (“SOG”) materials include, among others, siloxanes or silicates, which are often mixed with alcohol-based solvents or the like. SOG can be a desirable material because of the low temperatures (e.g., 150 to 250 degree C.) often needed to cure the SOG after it is applied to surfaces of the wafers.

Alternatively, a variety of other low temperature techniques can be used to join the substrate surface region to the handle substrate. For instance, an electro-static bonding technique can be used to join the two substrates together. In particular, one or both substrate surface(s) is charged to attract to the other substrate surface. Additionally, the donor substrate surface can be fused to the handle wafer using a variety of other commonly known techniques. Of course, the technique used depends upon the application.

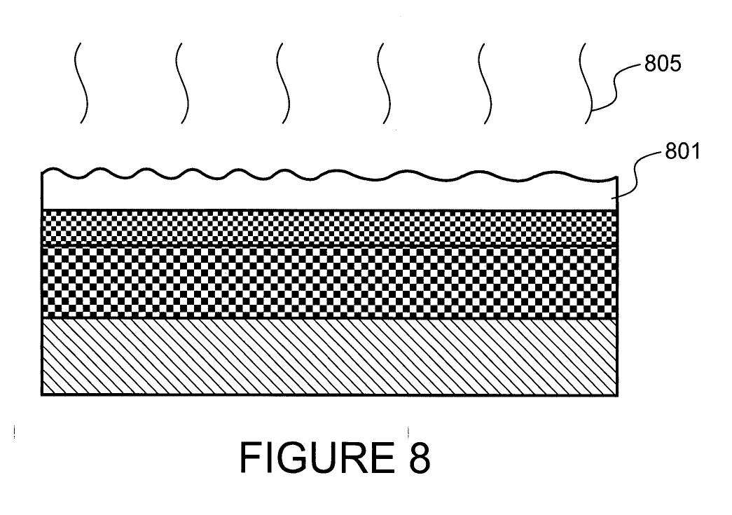

In a specific embodiment, the method selectively removes the first handle substrate from the thickness of semiconductor material, while the face of the second handle substrate remains joined to the planarized surface region, as illustrated by FIG. 8. In a specific embodiment, the method uses a selective etching solution 805 to selectively remove the handle substrate 801 from the thickness of material. In a preferred embodiment, the solution is hydrofluoric acid if the first handle material is quartz or glass. Other etching techniques such as plasma etching, reactive ion etching, ion milling, and other gas phase etching processes may be used, depending upon the specific embodiment. Of course, there can be other variations, modifications and alternatives.

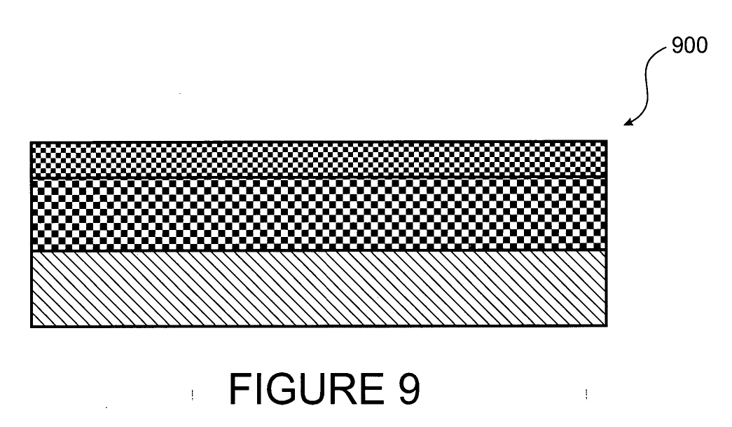

Optionally, the method can use a combination of techniques to remove the first handle substrate from the thickness of material to form a resulting substrate 900, as illustrated by FIG. 9. In a specific embodiment, the method can apply a grinding process, such as “back grind” to remove a certain thickness of material from the handle substrate. After such material has been removed, the method can selectively remove any remaining material 801 using a selective etching process, which may be a dry and/or wet etching process according to a specific embodiment. Alternatively, the method can use a chemical mechanical polishing process to remove a certain thickness of the handle substrate according to a specific embodiment. That is, chemical mechanical polishing can be used in combination with any of the techniques described herein, as well as other, and can be used alone according to a specific embodiment. One common approach is to backgrind the first handle wafer until the residual thickness is about 100-200 microns in thickness. The balance of the thickness until the actual silicon layer has been reached or an etch stop in proximity has been reached can be made using an appropriate etching solution. For glass or quartz, this can be hydrofluoric acid. The etch stop can either be the transferred film of silicon or a layer disposed between the silicon film and the first handle substrate. One example is an oxynitride or silicon nitride layer that would have different etch properties than the first handle substrate.

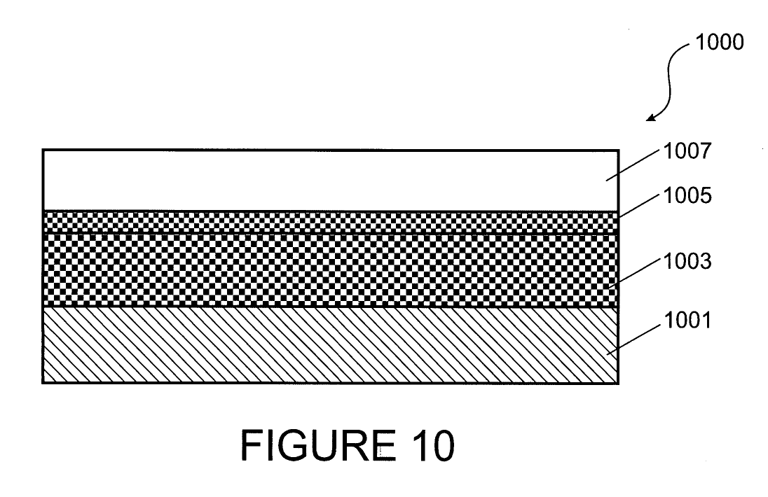

Additionally processes may include repeating the layer transfer processes to form resulting multi-layered substrate structure 1000 according to a specific embodiment, as illustrated by FIG. 10. The structure 100 includes bulk substrate 1001. The bulk substrate includes an overlying layer 1003, which may be a layer transferred layer. The overlying layer 1003 includes layer transferred layer 1005, which has processed and completed device structures thereon. Overlying layer 1005 includes one or more layers 1007, which also may be layer transferred, deposited, or any combination of these, according to a specific embodiment. Of course, there can be other variations, modifications, and alternatives.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A method for fabricating one or more devices, the method comprising:
providing a substrate, the substrate having a thickness of semiconductor material and a surface region, the substrate also having a cleave plane provided within the substrate and defining the thickness of semiconductor material;
joining the surface region of the substrate to a first handle substrate;
initiating a controlled cleaving action at a portion of the cleave plane to cause a detachment of the thickness of semiconductor material from the substrate, while the thickness of semiconductor material remains joined to the first handle substrate;
processing the first handle substrate with the thickness of semiconductor material using one or more processes to form at least one integrated circuit device onto a portion of the thickness of semiconductor material;
forming a planarized surface region overlying the thickness of semiconductor material;
joining the planarized surface region to a face of a second handle substrate; and
selectively removing the first handle substrate from the thickness of semiconductor material, while the face of the second handle substrate remains joined to the planarized surface region.

2. The method of claim 1 wherein the substrate is a silicon wafer.

3. The method of claim 1 wherein the substrate comprises a silicon bearing material.

4. The method of claim 1 wherein the thickness of semiconductor material is single crystal silicon material.

5. The method of claim 1 wherein the substrate comprises at least one layer.

6. The method of claim 1 wherein the substrate comprises a multilayered structure.

7. The method of claim 1 wherein the cleave plane comprises a plurality of particles.

8. The method of claim 1 wherein the cleave plane comprises a plurality of hydrogen bearing particles.

9. The method of claim 1 wherein the cleave plane comprises a strained region.

10. The method of claim 1 wherein the cleave plane comprises a deposited material.

11. The method of claim 1 wherein the cleave plane comprises a weakened region.

12. The method of claim 1 wherein the controlled cleaving action forms a single propagating cleave front on the portion of the cleave plane to detach the thickness of material from the substrate.

13. The method of claim 1 wherein the controlled cleaving action forms more than one propagating cleave fronts on the portion of the cleave plane to detach the thickness of material from the substrate.

14. The method of claim 1 wherein the joining of the surface region of the substrate to the first handle substrate is provided by a bonding process.

15. The method of claim 1 wherein the joining comprises a plasma activation bonding process.

16. The method of claim 1 wherein the joining comprises a bonding process selected from a glue process, an electro static process, a wet activation process, an anodic process, and an inorganic glue process.

17. The method of claim 1 wherein the first handle substrate comprises a glass material.

18. The method of claim 1 wherein the first handle substrate comprises a quartz material.

19. The method of claim 1 wherein the first handle substrate is selected from a glass plate, a quartz substrate, a conductive material, a composite material, a semiconductor material, a polymer material, a metal material, and a non-organic composite material.

20. The method of claim 1 wherein the one integrated circuit device comprises a MOSFET.

21. The method of claim 1 wherein the one integrated circuit device comprises a CMOS device.

22. The method of claim 1 wherein the one integrated circuit device is selected from a bipolar device, a CMOS device, a MOSFET, and a thin film transistor.

23. The method of claim 1 wherein the second handle substrate is selected from a semiconductor substrate, a silicon substrate, a quartz substrate, a glass substrate, a metal substrate, and a polymer substrate.

24. The method of claim 1 wherein the planarized surface region comprises an oxide bearing material.

25. The method of claim 1 wherein the planarized surface region is selected provided by a chemical mechanical polishing process, a reflow process, an etch back process, or a deposition process.

26. The method of claim 1 wherein the selectively removing comprises a selective etching process to remove the first handle substrate from the thickness of semiconductor material.

27. The method of claim 1 wherein the selectively removing comprises a selective etching process using a fluoride bearing species to remove the first handle substrate from the thickness of semiconductor material.

28. A method for fabricating one or more devices using a layer transfer process, the method comprising:
providing a semiconductor substrate, the semiconductor substrate having a thickness of semiconductor material and a surface region, the semiconductor substrate also having a cleave plane including a plurality of hydrogen species provided within the semiconductor substrate and defining the thickness of semiconductor material;
joining the surface region of the semiconductor substrate to a first handle substrate;
initiating a cleaving action at a portion of the cleave plane to cause detachment of the thickness of semiconductor material from the semiconductor substrate, while the thickness of semiconductor material remains joined to the first handle substrate;
processing the first handle substrate with the thickness of semiconductor material using one or more processes to form at least one integrated circuit device onto a portion of the thickness of semiconductor material;
forming a planarized surface region overlying the thickness of semiconductor material, the planarized surface region being capable of a bonding process;
joining the planarized surface region using at least a bonding process to a face of a second handle substrate; and
selectively removing the first handle substrate from the thickness of semiconductor material, while the face of the second handle substrate remains joined to the planarized surface region.

29. The method of claim 28 wherein the semiconductor substrate is a silicon wafer.

30. The method of claim 28 wherein the semiconductor substrate comprises a silicon bearing material.

31. The method of claim 28 wherein the thickness of semiconductor material is single crystal silicon material.

32. The method of claim 28 wherein the semiconductor substrate comprises at least one layer.

33. The method of claim 28 wherein the semiconductor substrate comprises a multilayered structure.

34. The method of claim 28 wherein the cleave plane comprises a strained region.

35. The method of claim 28 wherein the cleave plane comprises a deposited material.

36. The method of claim 28 wherein the cleave plane comprises a weakened region.

37. The method of claim 28 wherein the cleaving action comprises a controlled cleaving action to form a single propagating cleave front on the portion of the cleave plane to detach the thickness of material from the substrate.

38. The method of claim 37 wherein the controlled cleaving action forms more than one propagating cleave fronts on the portion of the cleave plane to detach the thickness of material from the substrate.

39. The method of claim 28 wherein the joining of the surface region of the substrate to the first handle substrate is provided by a thermal bonding process.

40. The method of claim 28 wherein the joining comprises a plasma activation bonding process.

41. The method of claim 28 wherein the bonding process selected from a glue process, an electro static process, a wet activation process, an anodic process, and an inorganic glue process.

42. The method of claim 28 wherein the first handle substrate comprises a glass material.

43. The method of claim 28 wherein the first handle substrate comprises a quartz material.

44. The method of claim 28 wherein the first handle substrate is selected from a glass plate, a quartz substrate, a conductive material, a composite material, a semiconductor material, a polymer material, a metal material, and a non-organic composite material.

45. The method of claim 28 wherein the one integrated circuit device comprises a MOSFET.

46. The method of claim 28 wherein the one integrated circuit device comprises a CMOS device.

47. The method of claim 28 wherein the one integrated circuit device is selected from a bipolar device, a CMOS device, a MOSFET, and a thin film transistor.

48. The method of claim 28 wherein the second handle substrate is selected from a semiconductor substrate, a silicon substrate, a quartz substrate, a glass substrate, a metal substrate, and a polymer substrate.

49. The method of claim 28 wherein the planarized surface region comprises an oxide bearing material.

50. The method of claim 28 wherein the planarized surface region is selected provided by a chemical mechanical polishing process, a reflow process, an etch back process, or a deposition process.

51. The method of claim 28 wherein the selectively removing comprises a selective etching process to remove the first handle substrate from the thickness of semiconductor material.

52. The method of claim 28 wherein the selectively removing comprises a selective etching process using a fluoride bearing species to remove the first handle substrate from the thickness of semiconductor material.
